(19) United States
(12) Patent Application Publication
(10) Pub. No.: US 2010/0154854 A1
(43) Pub. Date: Jun. 24, 2010

(54) THERMOELECTRIC MODULE COMPRISING SPHERICAL THERMOELECTRIC ELEMENTS AND METHOD OF MANUFACTURING THE SAME

(75) Inventors: Kyu-hyoung LEE, Yongin-si (KR); Sang-mock LEE, Yongin-si (KR); Chang-won HWANG, Anyang-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KP)

(21) Appl. No.: 12/618,473

(22) Filed: Nov. 13, 2009

(30) Foreign Application Priority Data
Dec. 19, 2008 (KR) 10-2008-0130379

(51) Int. Cl. H01L 35/34; H01L 35/02

(52) U.S. Cl. 136/201; 136/230

(57) ABSTRACT

A thermoelectric module includes; an upper substrate on which a plurality of upper electrodes having a plurality of first concave grooves formed therein are arranged, a lower substrate, on which a plurality of lower electrodes having a plurality of second concave grooves formed therein are arranged, and a least one spherical p-type thermoelectric element and at least one spherical n-type thermoelectric element interposed between the upper substrate and the lower substrate, and electrically and alternately in contact with the upper substrate and the lower substrate, wherein the at least one spherical p-type thermoelectric element and the at least one spherical n-type thermoelectric element are connected to the plurality of first concave grooves and the plurality of second concave grooves respectively disposed in the upper electrodes and the lower electrodes.

### CROSS-REFERENCE TO RELATED APPLICATION

This application claims priority to Korean Patent Application No. 10-2008-0130379, filed on Dec. 19, 2008, and all the benefits accruing therefrom under 35 U.S.C. §119, the contents of which in its entirety are herein incorporated by reference.

### BACKGROUND

1. Field

One or more exemplary embodiments relate to a thermoelectric module including spherical thermoelectric elements and a method of manufacturing the thermoelectric module, and more particularly, to an exemplary embodiment of a thermoelectric module including spherical thermoelectric elements, which has a reduced defect rate, and can be automated and mass produced by improving the form of the thermoelectric elements, wherein the thermoelectric module is formed of an insulating substrate, a metal electrode, and the thermoelectric elements.

2. Description of the Related Art

A thermoelectric effect denotes a reversible and direct energy conversion between heat and electricity and is generated due to movement of electrons and so called electron holes, e.g., missing valence electrons, within elements. Such a thermoelectric effect may be classified into a Peltier effect and a Seebeck effect, wherein the Peltier effect describes a cooling field using a temperature difference between both ends of an element generated by a current applied from the outside and the Seebeck effect describes a power generating field using an electromotive force generated by a temperature difference between both ends of an element.

The demand for cooling and power generation is increasing in a variety of fields, especially in fields where a system using general cooling gas compression, such as an active type cooling system and a precision temperature control system applied to DNA, cannot be used to resolve heat generating problems in temperature-sensitive electronic devices. Thermoelectric cooling is an environmentally friendly cooling technology with no-vibration and low-noise, which omits the use of refrigerant gases that may cause environmental problems. The field of application of thermoelectric cooling may be expanded, for example, a general-purpose cooling field such as refrigerators or air conditioners may use thermoelectric cooling due to the development of high-efficiency thermoelectric cooling elements. In addition, when the thermoelectric elements are applied to locations where heat is emitted such as engines of vehicles and industrial plants, heat generation is possible due to a temperature difference generated between both ends of the element. Such a thermoelectric heat generating system may be used in space exploration satellites where solar energy cannot be used.

A typical thermoelectric module employing the thermoelectric system is formed of an insulating substrate, a metal electrode, and thermoelectric elements. Such a typical thermoelectric module has a structure in which a p-type device and an n-type device are respectively connected in series, wherein in the p-type device, electron holes are moved and in the n-type device, electrons are moved. When a direct current (“DC”) power source is applied to both ends of the thermoelectric module, the electron holes and the electrons, which are both charge-carriers, are moved so that heat is generated in one side of the element and other end of the element is cooled.

### SUMMARY

One or more exemplary embodiments include a thermoelectric module, which has a reduced defect rate and is capable of being automated and mass-produced.

One or more exemplary embodiments include a method of manufacturing the thermoelectric module.

Additional aspects will be set forth in part in the description which follows and, in part, will be apparent from the description, or may be learned by practice of the invention.

To achieve the above and/or other aspects, one or more exemplary embodiments may include a thermoelectric module including; an upper substrate, on which a plurality of upper electrodes having a plurality of first concave grooves formed therein are arranged, a lower substrate, on which a plurality of lower electrodes having a plurality of second concave grooves formed therein are arranged, and at least one spherical p-type thermoelectric element and at least one spherical n-type thermoelectric element interposed between the upper substrate and the lower substrate, and electrically and alternately in contact with the upper substrate and the lower substrate, wherein the at least one spherical p-type thermoelectric element and the at least one n-type thermoelectric element are connected to the plurality of first concave grooves and the plurality of second concave grooves respectively disposed in the upper electrodes and the lower electrodes.

In one exemplary embodiment, the plurality of first grooves and the plurality of second grooves may have curved concave surfaces.

In one exemplary embodiment, the plurality of first grooves and the plurality of second grooves may have smaller diameters than the diameters of the at least one spherical p-type thermoelectric element and the at least one n-type thermoelectric element.

In one exemplary embodiment, the plurality of first grooves may have diameters that are one of the same as and different from the diameters of the second grooves.

In one exemplary embodiment, the plurality of first grooves and the plurality of second grooves may have a depth of about 0.1 mm to about 1 mm.

In one exemplary embodiment, the plurality of first grooves may have depths that are one of the same as and different from the depths of the plurality of second grooves.

In one exemplary embodiment, the depths of the plurality of first grooves and the plurality of second grooves may be predetermined to control effective lengths and effective areas of the at least one spherical p-type thermoelectric element and the at least one spherical n-type thermoelectric element.

To achieve the above and/or other aspects, one or more exemplary embodiments may include a method of manufacturing a thermoelectric module, the method including; patterning lower electrodes on a lower substrate and forming first concave grooves in the lower electrodes, providing a plurality of spherical p-type thermoelectric elements and a plurality of spherical n-type thermoelectric elements, arranging the plurality of spherical p-type thermoelectric elements and the plurality of spherical n-type thermoelectric elements on the second concave grooves disposed in the lower electrodes, thereby connecting the plurality of spherical p-type thermoelectric elements and the plurality of spherical n-type thermoelectric elements to the first concave grooves, patterning upper electrodes on an upper substrate and forming second concave grooves in the upper electrodes, and connecting the second concave grooves to the plurality of spherical p-type thermoelectric elements and the plurality of spherical n-type thermoelectric elements disposed on the lower substrate.

In one exemplary embodiment, the arranging of the plurality of spherical p-type thermoelectric elements and the plurality of spherical n-type thermoelectric elements on the upper electrodes and the lower electrodes may be performed using sieve-form frames having holes matching locations on the upper electrodes and the lower electrodes, where the plurality of spherical p-type thermoelectric elements and the plurality of spherical n-type thermoelectric elements are to be formed.

### BRIEF DESCRIPTION OF THE DRAWINGS

The above and/or other aspects, advantages and features of the exemplary embodiments will become more apparent and more readily appreciated from the following description of the exemplary embodiments, taken in conjunction with the accompanying drawings, of which:

FIG. 1 illustrates a thermoelectric module;

FIG. 2 is an enlarged partial cross-sectional view of an exemplary embodiment of a thermoelectric module;

FIG. 3 is an enlarged partial cross-sectional view of an exemplary embodiment of a substrate including an electrode having concave grooves disposed therein;

FIG. 4A is an enlarged partial cross-sectional view of an exemplary embodiment of a thermoelectric module;

FIG. 4B is an enlarged partial cross-sectional view of an exemplary embodiment of a thermoelectric module;

FIG. 5 is an enlarged partial cross-sectional view of an exemplary embodiment of a thermoelectric module;

FIG. 6 illustrates an exemplary embodiment of a lower substrate including lower electrodes;

FIG. 7 is a front perspective view of an exemplary embodiment of a lower substrate in which thermoelectric elements are combined;

FIG. 8 is an enlarged partial cross-sectional view of an exemplary embodiment of an upper substrate including upper electrodes;

FIG. 9 is an enlarged cross-sectional view of an exemplary embodiment of a lower substrate including an electrode having concave grooves filled with a bonding agent;

FIG. 10 is a front perspective view of an exemplary embodiment of a thermoelectric module; and

FIG. 11 is a front perspective view of an exemplary embodiment of spherical thermoelectric element.

### DETAILED DESCRIPTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in detail with reference to the accompanying drawings.

Reference will now be made in detail to exemplary embodiments, examples of which are illustrated in the accompanying drawings.

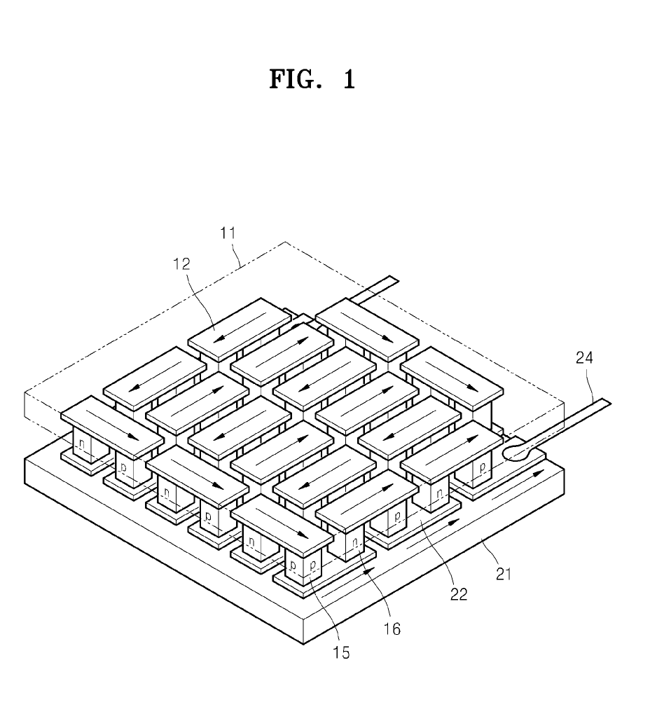

FIG. 1 illustrates a thermoelectric module including structures in which p-type thermoelectric elements 15 and n-type thermoelectric elements 16 are interposed between an upper substrate 11 and a lower substrate 21 and are electrically connected to the upper substrate 11 and the lower substrate 21, wherein the upper substrate 11 includes upper electrodes 12 patterned thereon and the lower substrate 21 includes lower electrodes 22 patterned thereon.

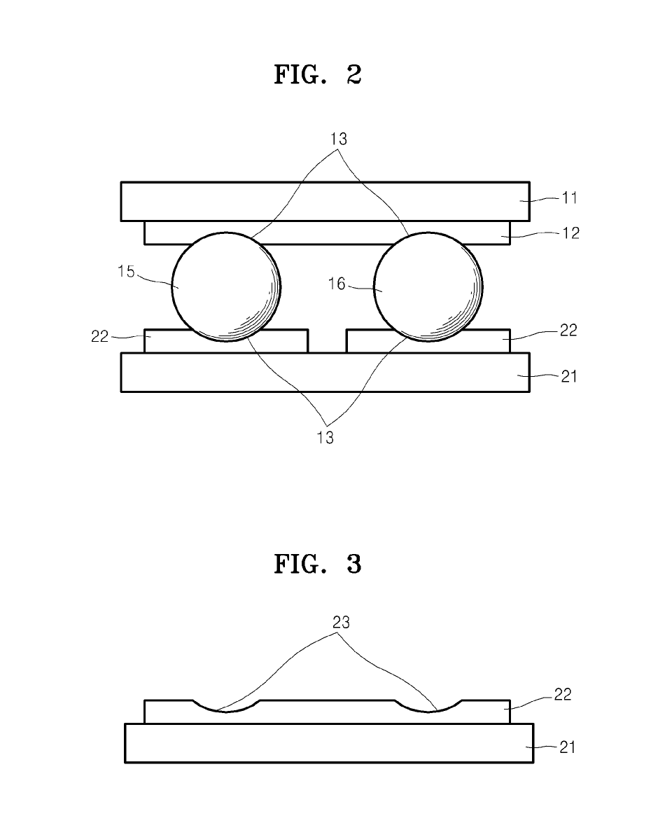

In the present exemplary embodiment, thermoelectric elements used in the thermoelectric module are spherical. Connection parts between the electrodes and the thermoelectric elements according to the present exemplary embodiment are enlarged and illustrated in FIG. 2. As illustrated in FIG. 2, first concave grooves 13 are formed in the upper electrodes 12 and second concave grooves 23 are formed in the lower electrodes 22, and are each connected to the spherical thermoelectric elements 15 and 16, respectively. Since the spherical thermoelectric elements 15 and 16 are disposed to be in contact with the first concave grooves 13 and the second concave grooves, movement of thermoelectric elements 15 and 16, which may be generated due to mobility of solder due to heat during contraction, may be prevented and thus, the thermoelectric elements 15 and 16 do not contact each other, thereby reducing a defect rate. Specifically, the first concave grooves 13, the second concave grooves 23 and the spherically shaped thermoelectric elements 15 and 16 prevent movement of the thermoelectric elements 15 and 16 if the solder fixing them in position is loosened due to heating, e.g., due to operation of the thermoelectric device.

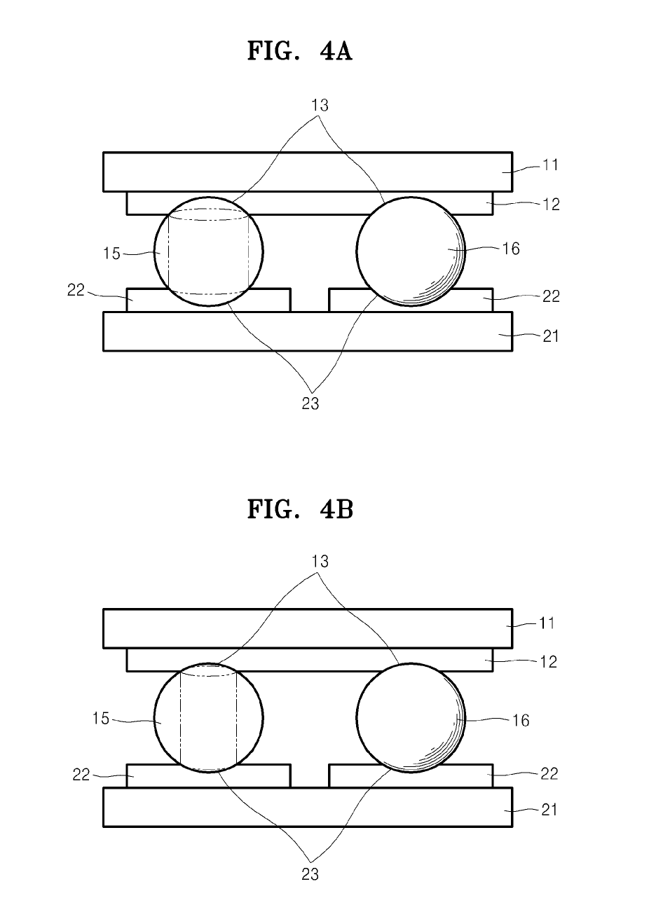

The first concave grooves 13 and the second concave grooves 23 disposed in the upper electrodes 12 and the lower electrodes 22, respectively, may have a hemispherical concave form so as to facilitate connection between the first and second concave grooves 13 and 23 and the spherical thermoelectric elements 15 and 16, as illustrated in FIG. 3, and the first and second grooves 13 and 23 may be shaped to have a curved concave surface. Exemplary embodiments include configurations wherein the depth of the first and second concave grooves 13 and 23 may be varied, e.g., in one exemplary embodiment, the depth of the first and second concave grooves 12 and 23 may be slightly less than half a thickness of the thermoelectric elements 15 and 16. The form of the first and second concave grooves 13 and 23 may vary according to their depth and diameter as illustrated in FIGS. 4A and 4B. When the first and second concave grooves 13 and 23 have a large diameter and depth, the surface area connecting with the spherical thermoelectric elements 15 and 16 may be greater as shown in FIG. 4A, and when the grooves have small diameter and depth, the surface area connecting with the spherical thermoelectric elements may be lessened as shown in FIG. 4B.

When a large surface area of the first and second concave grooves 13 and 23 is in contact with the thermoelectric elements 15 and 16, as illustrated in FIG. 4A, the contact surface with respect to the effective length of the thermoelectric elements 15 and 16 increases. When a small surface area of the first and second concave grooves 13 and 23 is in contact with the thermoelectric elements 15 and 16, as illustrated in FIG. 4B, the contact surface with respect to the effective length of the thermoelectric elements 15 and 16 decreases. That is, as the diameters and depths of the first and second concave grooves 13 and 23 disposed on the upper electrodes 12 and the lower electrodes 22 are adjusted, effective lengths and effective areas of the thermoelectric elements 15 and 16, which actually operate, may vary and thus, the thermoelectric module may be controlled to uniformly perform functions throughout an entire device.

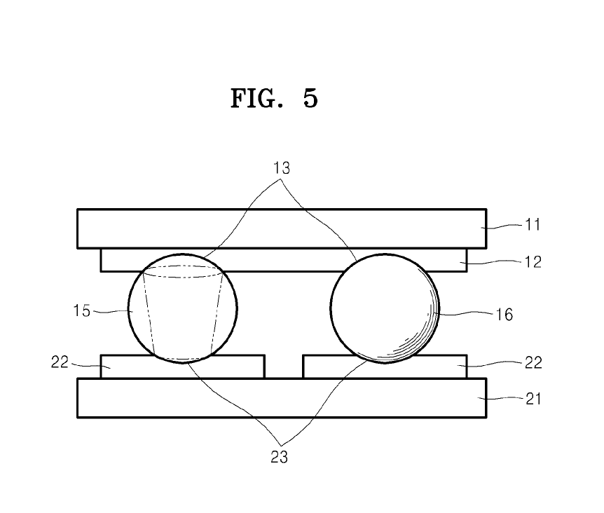

In addition, adjustment of the diameters and depths of the first and second grooves 13 and 23 may be separately applied to the upper electrodes 12 and the lower electrodes 22 so that adjustment using different operational effective areas of the thermoelectric elements in a high-temperature side and a low-temperature side is possible as shown in FIG. 5.

In one exemplary embodiment, the depths of the first concave grooves 13 disposed in the upper electrodes 12 and the second concave grooves 23 disposed in the lower electrodes 22 are, for example, about 0.1 mm to about 1 mm.

A method of manufacturing the exemplary embodiment of a thermoelectric module according to the present exemplary embodiment includes: (a) patterning the lower electrodes 22 on the lower substrate 21 and forming the second concave grooves 23 in the lower electrodes 22; (b) forming the p-type thermoelectric elements 15 and the n-type thermoelectric elements 16 in a spherical form; (c) arranging the spherical p-type thermoelectric elements 15 and n-type thermoelectric elements 16 on the second concave grooves 23 disposed in the lower electrodes 22, thereby connecting the spherical p-type thermoelectric elements 15 and n-type thermoelectric elements 16 to the second concave grooves 23; (d) patterning the upper electrodes 12 on the upper substrate 11 and forming the first concave grooves 13 in the upper electrodes 12; and (e) connecting the first concave grooves 13 with the spherical p-type thermoelectric elements 15 and n-type thermoelectric elements 16 disposed on the lower substrate 21. However, alternative exemplary embodiments include configurations wherein the order of the above steps may be alternately arranged.

The exemplary embodiment of a method of manufacturing the exemplary embodiment of a thermoelectric module will now be described in more detail.

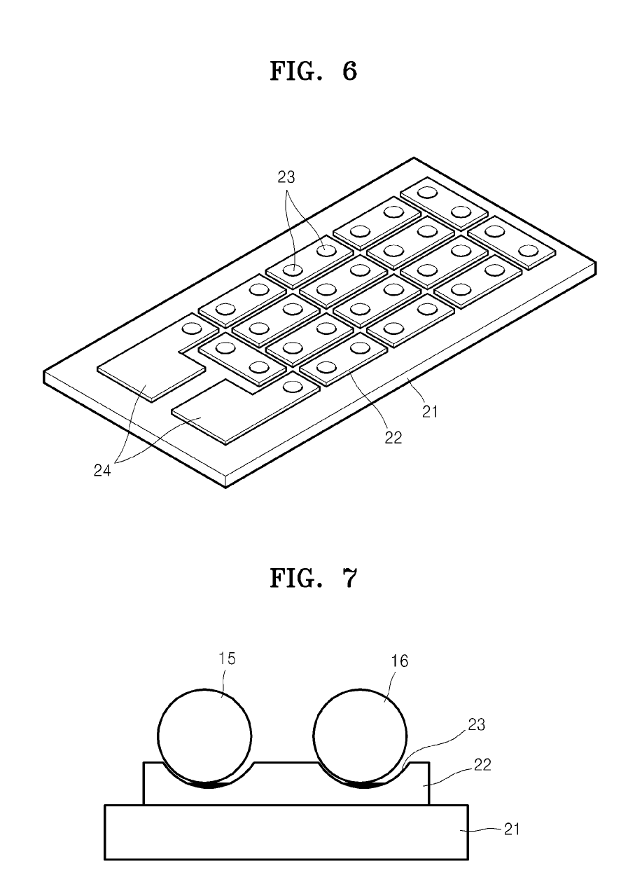

As illustrated in FIG. 6, a plurality of lower electrodes 22 is patterned on the lower substrate 21 and then the second concave grooves 23 are formed in the surfaces of the lower electrodes 22.

The lower substrate 21 may include insulator ceramics, exemplary embodiments of which include alumina (Al₂O₃), aluminum nitride (AlN), boron nitride (BN), zirconia (ZrO₂) or other similar materials. The material of the lower electrodes 22 may include copper (Cu), copper-molybdenum (Cu−Mo), silver (Ag), gold (Au), platinum (Pt), other materials having similar characteristics or combinations thereof, all of which have excellent electrical conductivity, and the size of the material may vary. A general patterning method may be used in patterning the lower electrodes 22. In one exemplary embodiment, the patterning method may include, for example, deposition such as a direct bonding method and an e-beam coating method, and a method using a bonding agent such as AgPd. The lower electrodes 22 are divided into a number of pieces, each including two second concave grooves 23. Also, lead electrodes 24 connected to the lower electrodes 22 are disposed at an end part of the lower substrate 21.

An exemplary embodiment of a method of forming the second grooves 23 in the surfaces of the lower electrodes 22 may include a mechanical method such as punching and a chemical method such as etching, but is not limited thereto.

Next, a bonding agent is applied to the second grooves 23 formed in the lower electrodes 22. In one exemplary embodiment solder may be used as the bonding agent. An amount of bonding agent that is sufficient to bond the spherical thermoelectric elements 15 and 16 is used.

Then, as illustrated in FIG. 7, the p-type thermoelectric elements 15 and the n-type thermoelectric elements 16 are arranged to be fixed into the second grooves 23, in which the bonding agent (not shown) is filled. The p-type thermoelectric elements 15 are arranged in one part of the lower electrodes 22 and the n-type thermoelectric elements 16 are arranged in another part of the lower electrodes 22, and the arrangement of the p-type and n-type thermoelectric elements 15 and 16 is performed manually or by an automation process, e.g., using a robot.

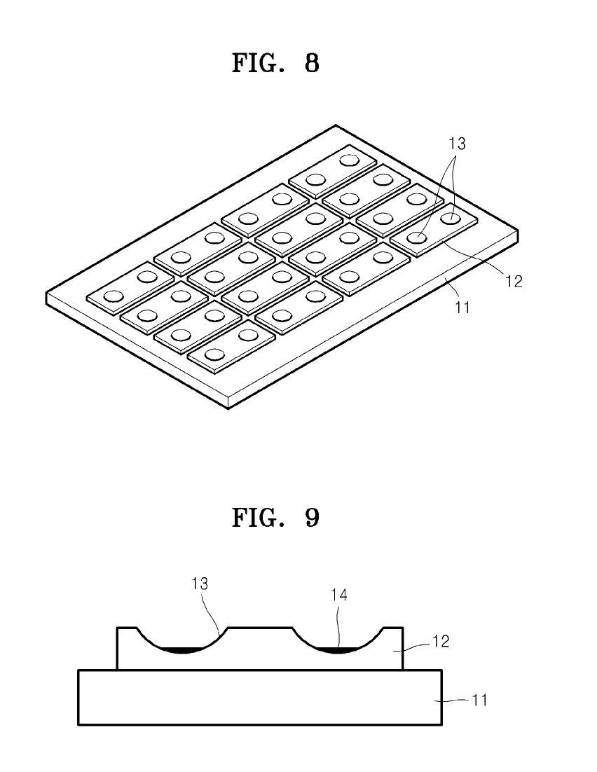

Separately from the lower substrate 21, on which the lower electrodes 22 are patterned, the upper substrate 11, on which a plurality of upper electrodes 12 are formed, is formed using substantially the same method of forming the lower substrate 21. Alternative exemplary embodiments include configurations wherein the upper substrate 11 and upper electrodes 12 are formed in a different manner than the lower substrate 21 and the lower electrodes 22. Also, the first concave grooves 13 are formed in the upper electrodes 12 using substantially the same method of forming the second grooves 23. Alternative exemplary embodiments include configurations wherein the first concave grooves 13 are formed in a different manner than the second concave grooves 23. The upper substrate 11, on which a plurality of upper electrodes 12 including the first concave grooves 13 is formed, is illustrated in FIG. 8.

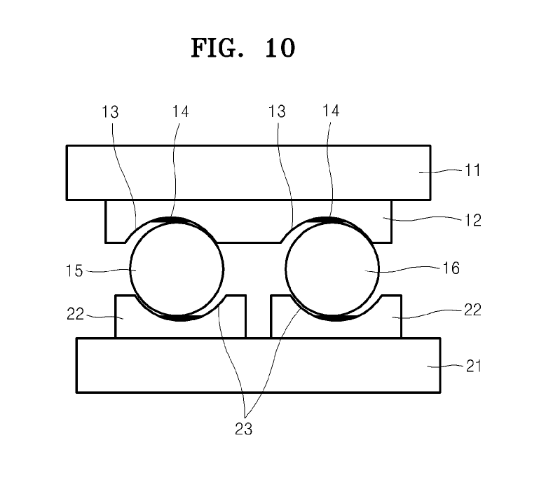

As illustrated in FIG. 9, a bonding agent 14, e.g., solder, is filled in the first concave grooves 13 formed in the upper electrodes 12 and then, the upper substrate 11, on which a plurality of upper electrodes 12 including the first concave grooves 13, in which the bonding agent 14 is filled, are formed, is combined with the lower substrate 21, on which the p-type and n-type thermoelectric elements 15 and 16 are arranged. During the combining process, the first concave grooves 13 are fixed to the p-type thermoelectric elements 15 and the n-type thermoelectric elements 16. The combined part is enlarged and is illustrated in FIG. 10.

When the combining process is completed, the p-type thermoelectric elements 15 and the n-type thermoelectric elements 16 are combined to the upper and lower substrates 11 and 21, thereby completing the manufacture of the thermoelectric module.

The arrangement of the p-type thermoelectric elements 15 and the n-type thermoelectric elements 16 are performed to fix them to the second grooves 23 formed on the lower electrodes 22, so that the spherical p-type thermoelectric elements 15 and n-type thermoelectric elements 16 are arranged in the second grooves 23 of the lower electrodes 22 formed on the lower substrate 21 after the bonding agent 14 is applied. Accordingly, the p-type thermoelectric elements 15 are arranged in one part of the lower electrodes 22 and the n-type thermoelectric elements 16 are arranged in another part of the lower electrodes 22, wherein the p-type thermoelectric elements 15 and n-type thermoelectric elements 16 are uniformly arranged. Thus, each one of the thermoelectric elements 15 and 16 may be disposed on corresponding locations. In one exemplary embodiment, the thermoelectric elements 15 and 16 may be arranged manually. Alternative exemplary embodiments also include configurations wherein an automation process to arranged the thermoelectric elements 15 and 16 may be performed by a robot.

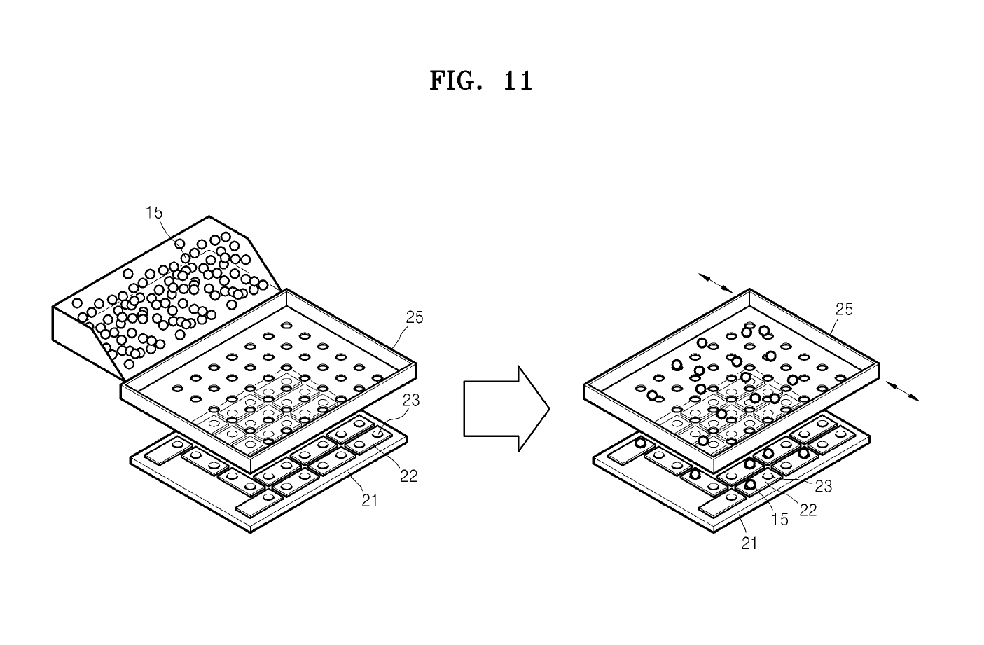

According to the present exemplary embodiment, the arrangement of the thermoelectric elements may be automated using a sieve-form frame 25. That is, as illustrated in FIG. 11, the sieve-form frame 25 having holes matching the second concave grooves 23 disposed in the lower electrodes 22 is used and the p-type spherical thermoelectric elements 15 are applied through the holes, e.g., by vibration, so that the p-type thermoelectric elements 15 are arranged to be fixed in the second grooves 23 disposed in the lower electrodes 22. A sieve-form frame matching the p-type thermoelectric elements 15 and a sieve-form frame matching the n-type thermoelectric elements 16 are separately prepared and these two sieve-form frames are respectively sequentially used to arrange the p-type thermoelectric elements 15 and the n-type thermoelectric elements 16 in the second grooves 23 disposed in the lower substrate 21 by performing an arranging process twice. When such an arranging process is used, automation is possible without manual support. In addition, a number of thermoelectric elements 15 and 16 can be arranged simultaneously so that productivity increases and efficient mass-production is possible.

According to the present exemplary embodiment, the composition of the spherical thermoelectric elements 15 and 16 is not limited, and the spherical thermoelectric elements 15 and 16 may include at least two selected from the group consisting of bismuth (Bi), antimony (Sb), tellurium (Te), and selenium (Se).

For example, in one exemplary embodiment, a composition formula of the thermoelectric elements matrix may be [A]₂[B]₃ (here, A is Bi and/or Sb and B is Te and/or Se). In the exemplary embodiment wherein Bi-Te is used as the spherical thermoelectric elements 15 and 16, excellent thermoelectric performance is achieved near high-temperatures and thus Bi-Te may be used to emit light in highly integrated devices and various sensors.

The thermoelectric module according to the present exemplary embodiment may be a thermoelectric cooling system or a thermoelectric heat generating system, wherein the thermoelectric cooling system may comprise a micro-cooling system, a general-purpose cooling device, an air conditioner, or a waste heat recovery system, but is not limited thereto. The configuration and a manufacturing method of the thermoelectric cooling system are disclosed in the field to which the present exemplary embodiment pertains and thus a description thereof will be omitted here.

It should be understood that the exemplary embodiments described herein should be considered in a descriptive sense only and not for purposes of limitation. Descriptions of features or aspects within each exemplary embodiment should typically be considered as available for other similar features or aspects in other exemplary embodiments.

What is claimed is:

1. A thermoelectric module comprising:
an upper substrate, on which a plurality of upper electrodes having a plurality of first concave grooves formed therein are arranged;
a lower substrate, on which a plurality of lower electrodes having a plurality of second concave grooves formed therein are arranged; and
at least one spherical p-type thermoelectric element and at least one spherical n-type thermoelectric element interposed between the upper substrate and the lower substrate, and electrically and alternately in contact with the upper substrate and the lower substrate,
wherein the at least one spherical p-type thermoelectric element and the at least one spherical n-type thermoelectric element are connected to the plurality of first concave grooves and the plurality of second concave grooves respectively disposed in the upper electrodes and the lower electrodes.

2. The thermoelectric module of claim 1, wherein the plurality of first grooves and the plurality of second grooves have curved concave surfaces.

3. The thermoelectric module of claim 1, wherein the plurality of first grooves and the plurality of second grooves have smaller diameters than the diameters of the at least one spherical p-type thermoelectric element and the at least one spherical n-type thermoelectric element.

4. The thermoelectric module of claim 2, wherein the plurality of first grooves have diameters that are one of the same as and different from the diameters of the plurality of second grooves.

5. The thermoelectric module of claim 1, wherein the plurality of first grooves and the plurality of second grooves have a depth of about 0.1 mm to about 1 mm.

6. The thermoelectric module of claim 1, wherein the plurality of first grooves have depths that are one of the same as and different from the depths of the plurality of second grooves.

7. The thermoelectric module of claim 1, wherein the depths of the plurality of first grooves and the plurality of second grooves are predetermined to control effective lengths and effective areas of the at least one spherical p-type thermoelectric element and the at least one spherical n-type thermoelectric element.

8. A method of manufacturing a thermoelectric module, the method comprising:
patterning lower electrodes on a lower substrate and forming first concave grooves in the lower electrodes;
providing a plurality of spherical p-type thermoelectric elements and a plurality of spherical n-type thermoelectric elements;
arranging the plurality of spherical p-type thermoelectric elements and the plurality of spherical n-type thermoelectric elements on the first concave grooves disposed in the lower electrodes, thereby connecting the plurality of spherical p-type thermoelectric elements and the plurality of spherical n-type thermoelectric elements to the first concave grooves;
patterning upper electrodes on an upper substrate and forming second concave grooves in the upper electrodes; and
connecting the second concave grooves to the plurality of spherical p-type thermoelectric elements and the plurality of spherical n-type thermoelectric elements disposed on the lower substrate.

9. The method of claim 8, wherein the arranging of the plurality of spherical p-type thermoelectric elements and the plurality of spherical n-type thermoelectric elements on the upper electrodes and the lower electrodes is performed using sieve-form frames having holes matching locations on the upper electrodes and the lower electrodes where the plurality of spherical p-type thermoelectric elements and the plurality of spherical n-type thermoelectric elements are to be formed.
